(19) United States
(12) Patent Application Publication
(10) Pub. No.: US 2008/0265253 A1
(43) Pub. Date: Oct. 30, 2008

(54) THIN FILM TRANSISTOR DISPLAY PANEL, MANUFACTURING METHOD AND DETECTION METHOD THEREOF

(75) Inventors: Zhenhuan TIAN, Beijing (CN); Ki Young KWON, Beijing (CN)

Correspondence Address: SHERIDAN ROSS PC, 1560 BROADWAY, SUITE 1200, DENVER, CO, 80202, US

(73) Assignee: BEIJING BOE OPTOELECTRONICS TECHNOLOGY CO., LTD., Beijing (CN)

(21) Appl. No.: 12/045,851

(22) Filed: Mar. 11, 2008

(30) Foreign Application Priority Data
Apr. 25, 2007 (CN) 200710098706.6

(51) Int. Cl. H01L 27/105; H01L 21/77

(52) U.S. Cl. 257/59; 438/29; 257/E21.535; 257/E27.111

(57) ABSTRACT

A thin film transistor (TFT) display panel as well as a manufacturing method and a detection method thereof are provided. The TFT display panel comprises at least two display regions and a detection region, wherein a gate detection line is correspondingly connected at least with all the gate lines from one of the display regions in the detection region. The embodiments of the present invention improve the safety of the circuits in the detection region, and simplify the mask process of the TFT display panel and the detection process for the display region, which in turn increases the production efficiency of the TFT and reduces the production cost.

### FIELD OF THE INVENTION

The present invention relates to a liquid crystal display, and more particularly to a thin film transistor (TFT) display panel as well as a manufacturing method and a detection method thereof.

### BACKGROUND OF THE INVENTION

A thin film transistor (TFT) display panel of a thin film transistor liquid crystal display (TFT-LCD) device is manufactured by forming films on an insulating substrate such as a glass substrate and performing exposing and developing process on the films. During the initial stage of manufacturing, the TFT display panel comprises a display region on the insulating substrate, which is defined by gate lines and data lines intersecting with each other, and a peripheral detection region for detecting the circuits formed in the display region. Whether the circuits formed in the display region operate normally is determined by applying detection signals to the peripheral detection region to perform detection. If the circuits formed in the display region operate properly, the detection region is removed from the substrate, thus completing the manufacturing of the TFT display panel.

In the conventional manufacturing method and detection method of the TFT display panel, the TFT display panel during the initial stage of manufacturing is for example shown in FIG. 8A. Gate lines 621 and data lines 622 are led out of the display region 10. The storage capacitors Cs of pixels in the display region are formed on the gate lines adjacent to the pixels, and for example, as shown in FIG. 8B, the storage capacitors Cs in pixels 5 are disposed on the adjacent gate lines 41, 42, 43, and so on. In order to achieve enough capacitance so as to detect whether the pixels are properly formed, the gate lines are divided into groups of odd gate lines and even gate lines in the peripheral detection region, which are correspondingly connected with the odd gate detection lines 6211 and even gate detection lines 6212. The odd gate lines of each display region are connected with an odd gate detection line 6211, and the even gate lines of each display region are connected with an even gate detection line 6212. Odd gate detection pads 62111 are formed at two ends of the odd gate detection lines 6211, and even gate detection pads 62121 are formed at two ends of the even gate detection lines 6212. In the same way, the data lines are divided into groups of odd data lines and even data lines in the detection region. The odd data lines of each display region are connected with an odd data detection line 6221, and the even data lines of each display region are connected with an even data detection line 6222. Odd data detection pads 62211 are formed at two ends of the odd data detection lines 6221, and even data detection pads 62221 are formed at two ends of the even data detection lines 6222. During detection, the data detection signals are applied to the data lines via the pads at both ends of the odd and even data detection lines. When gate detection signals are applied to the odd gate lines 41, 43, and so on via the pads 62111 at both ends of the odd gate detections lines 6211, as shown in FIG. 8B, a voltage signal opposite to the data detection signal applied to the data line 3 is applied to the even gate lines 42 and so on via the pads 62121 at both ends of the even gate detection lines 6212, so as to charge the pixels controlled by the odd gate lines, or the gate detection signals are applied to the even gate lines, and a voltage signal opposite to the data detection signal applied to the data lines 3 is applied to the odd gate lines, so as to charge the pixels controlled by the even gate lines, so that the detection of the circuits in the display region 10 is accomplished to identify whether there are defects such as open circuit, short circuit, and bad pixel in the display region 10.

In the above conventional technology, the gate lines are directly formed on the insulating substrate and in the lowermost layer among all the thin films of the TFT display panel. However, it is impossible to be realized in the same layer of film to divide the gate lines into odd and even gate lines and correspondingly connect them with the odd and even gate detection lines in the detection region of the panel. Therefore, the odd gate detection lines and even gate detection lines are required to be arranged in different layers, and an insulating thin film is interposed between these layers to prevent the electrical conduction at the intersecting regions. In addition, the odd and even gate detection lines in different layers are connected with corresponding gate lines through via holes and conduction lines, so as to electrically separate the odd gate lines and even gate lines. However, in this manner, many intersecting regions are formed on the panel, which needs a complicated manufacturing process and brings about severe safety issues in the detection region, such as static breakthrough, signal crosstalk, poor processing, and the like. Furthermore, for the purpose of detection, two groups of pins are required to be provided for each display region to apply odd gate detection signals to the pads of the odd gate lines and even gate detection signals to the pads of the even gate lines, and the detection is carried out by adjusting the parameters of these two groups of gate detection signals, which increases the complexity of the detection and results in long production period, low efficiency, and high cost of the TFT display panel.

### SUMMARY OF THE INVENTION

An embodiment of the present invention provides a thin film transistor (TFT) display panel, comprising: at least two display regions, which are formed on an insulting substrate and each comprise gate lines, data lines, and common electrode lines arranged between the neighboring gate lines; and an detection region, which is formed on the insulating substrate and in the periphery of the display regions and comprises gate lines led out of the display region, a gate detection line for detection which is connected with the gate lines, a gate detection pad connected with the gate detection line, data lines led out of the display region, odd and even data detection lines for detection which are connected with the data lines, odd and even data detection pads correspondingly connected with the odd and even data detection lines, common electrode lines led out of the display region, a common electrode detection line connected with the common electrode lines, and a common electrode detection pad connected with the common electrode detection lines. The gate detection line is correspondingly connected at least with all gate lines from one of the display regions.

An embodiment of the present invention also provides a method for manufacturing a TFT display panel, comprising: forming on a substrate gate lines and common electrode lines of at least two display regions, and a gate detection line, odd and even data detection lines, a common electrode detection line, a gate detection pad, odd and even data detection pads, and a common electrode detection pad in a detection region in the periphery of the display regions, wherein the gate detection line is correspondingly connected with all gate lines from at least one of the display regions, and the common electrode detection line is connected with the common electrode lines, and the gate detection pad, odd and even data detection pads, and the common electrode detection pad are formed at an end of the gate detection line, odd and even data detection lines, the common electrode detection line, respectively; forming a gate insulating layer on the substrate and forming first via holes in the gate insulating layer which lead to the odd and even data detection lines, respectively; forming data lines and connecting the odd and even data lines with corresponding odd and even data detection lines respectively through the first via holes; and forming a passivation layer and second via holes in the passivation which expose the gate detection pads, the odd and even data detection pads, and the common electrode detection pads, respectively.

An embodiment of the present invention also provides a method for detecting the above TFT display panel, comprising: applying a gate detection signal to the gate lines through the gate detection pad; applying data detection signals to the odd and even data lines through the odd and even data detection pads, respectively; and applying a voltage signal opposite to the data detection signals applied to the odd and even data lines to the common electrode line through the common electrode detection pad, thereby performing detection on the display regions.

The embodiments of the present invention improve the safety of the circuits in the detection region, and simplify the mask process for the TFT display panel and the detection process for the display region of the TFT display panel, which in turn increases the production efficiency of the TFT and reduces the production cost.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from the following detailed description.

### BRIEF DESCRIPTION OF THE DRAWING

The present invention will become more fully understood from the detailed description given hereinafter and the accompanying drawings which are given by way of illustration only, and thus are not limitative of the present invention and wherein:

FIG. 1A is a structural schematic view of a thin film transistor (TFT) display panel according to an embodiment of the present invention;

FIG. 1B is an enlarged view of a portion of the display region in FIG. 1A;

FIG. 2 is a structural schematic view of a TFT display panel according to another embodiment;

FIG. 3 is a structural schematic view of a TFT display panel according to still another embodiment;

FIG. 4 is a structural schematic view of a TFT display panel according to yet still another embodiment;

FIG. 5 is a flowchart illustrating a method for manufacturing the TFT display panel according to an embodiment of the present invention;

FIG. 6 is a flowchart illustrating a method for manufacturing the TFT display panel according to another embodiment of the present invention;

FIG. 7A is a schematic view showing a stage in which the intersection region of the gate detection lines is formed in the gate metal film;

FIG. 7B is a schematic view showing a stage in which a gate insulating layer has been deposited on the intersection regions in FIG. 7A;

FIG. 7C is a schematic view showing a stage in which the intersection region in FIG. 7B is formed in the layer of the data metal film;

FIG. 8A is a schematic view showing a conventional TFT display panel; and

FIG. 8B is an enlarged view of a portion of the display region of the conventional TFT display panel.

### DESCRIPTION OF THE PREFERRED EMBODIMENTS

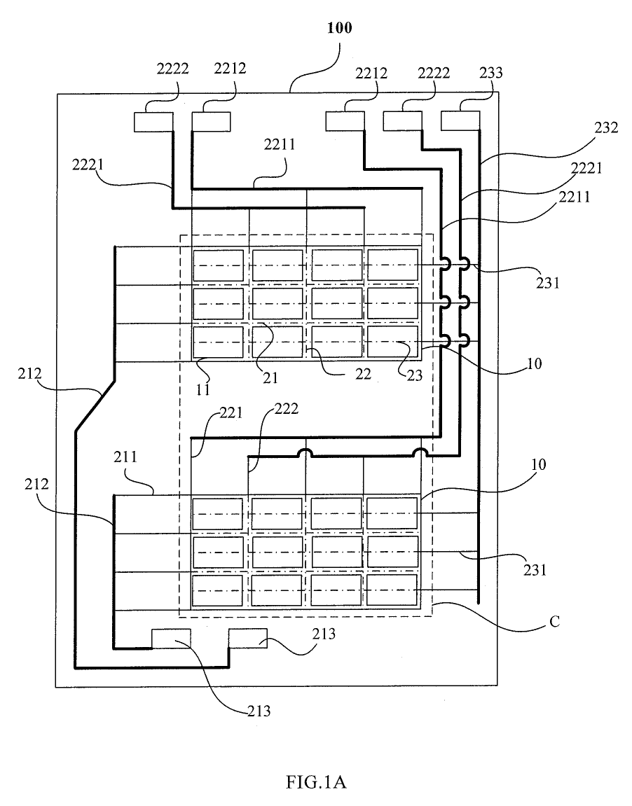

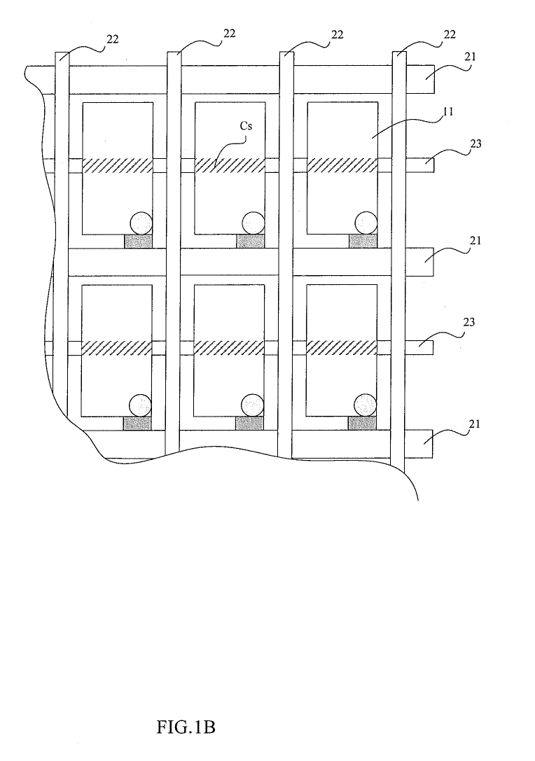

FIG. 1A is a structural schematic view of a TFT display panel 100 according to an embodiment of the present invention. The TFT display panel 100 comprises, for example, two display regions 10 and a detection region in the periphery of the display regions 10. The display regions 10 and the detection region are formed on the same insulating substrate such as a glass substrate. There may be more than two display regions 10.

Gate lines 21, data lines 22, and common electrode lines 23 are formed in the display regions 10. As shown in FIG. 1B, each display region 10 is divided by the gate lines 21 and data lines 22 into pixels 11, the common electrode lines 23 are arranged between adjacent gate lines 21, and storage capacitor Cs in each of the pixels 11 is arranged on the common electrode line 23. During detection, a voltage signal opposite to the data detection signal applied to the data lines is applied to the common electrode lines 23 through a common electrode detection pad, which allows the storage capacitors Cs have enough capacitance to realize the detection of the display region. In this way, there is no need to divide the gate lines 21 in the detection region into groups of odd gate lines and even gate lines, and the presence of intersections of the gate detection lines in the detection region also can be further avoided.

The detection region is the portion outside of the display region 10 of the TFT display panel 100, and in the detection region there are formed gate lines 211 led out of the display region 10; a gate detection line 212 for detection which is connected with the gate lines 211; a gate detection pad 213 connected with the gate detection line 212; odd and even data lines 221, 222 led out of the display region 10; odd and even data detection lines 2211, 2221 for detection which are correspondingly connected with the odd and even data lines 221, 222; odd and even data detection pads 2212, 2222 correspondingly connected with the odd and even data detection lines 2211, 2221; common electrode lines 231 led out of the display region 10; a common electrode detection line 232 connected with the common electrode lines 231; and a common electrode detection pad 233 connected with the common electrode detection line 232. Herein, the gate detection pad 213 is provided at one end of the gate detection line 212, the odd data detection pad 2212 is provided at one end of the respective odd data detection line 2211, the even data detection pad 2222 is provided at one end of the respective even data detection line 2221, and the common electrode detection pad 233 is provided at one end of the respective common electrode detection line 232.

Detection signals are applied to the pads 213, 2212, 2222, and 233 to detect whether the circuits in the display region 10 can operate properly. When it has determined that the circuits in the display region 10 operate properly, after the necessary subsequent processes, the detection region is removed along the dashed line C from the substrate, thus completing the manufacturing of the TFT display panel.

For example, as shown, the gate detection line 212 is connected with all the gate lines 211 from one of the display regions 10, and the gate lines 211 do not form any intersections with the gate detection line 212 in the embodiment. As a result, there is little overlapping between circuits, so that the circuits as required for gate detection can be formed with the same gate metal film. In this way, the mask process for the detection region is simplified, the safety issue of the circuits is reduced, and the probabilities of static breakthrough, signal crosstalk, poor processing and the like during detection is substantially decreased. Furthermore, during the detection on the circuits in the display region, only one kind of gate detection signals is applied to the gate detection pad to perform the detection on the circuits in the display region, so that the factors that may influence the detection result can be reduced and the reliability of signal input is improved. In addition, the simplification of the mask process and the detection process as well as the improvement of reliability also substantially shorten the production period of the TFT display panel, improve the production efficiency, and reduce the production cost.

In the above embodiment, the gate detection pad can also be arranged at the same side as the odd and even data detection pads.

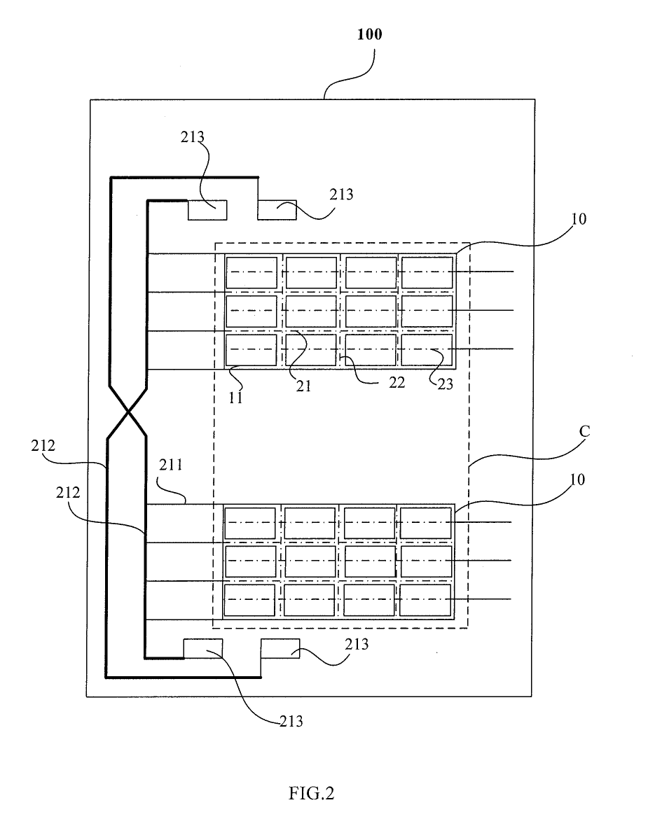

FIG. 2 is a structural schematic view of a TFT display panel according to another embodiment, in which the data line detection configuration in the detection region is the same as that of the embodiment illustrated in FIG. 1A and is not described again here for simplicity. One gate detection line 212 is correspondingly connected with all the gate lines 211 from one of the display regions 10, and gate detection pads 213 are provided at both ends of the gate detection line 212. As a result, in the case that the insulating substrate is in a relatively large area, detection signals can be applied at the either side of the panel for detection, which further reduces the detection time, improves the production efficiency of the TFT display panel, and reduces the production cost. As shown in FIG. 2, the two gate detection lines 212 intersect with each other.

FIG. 3 is a structural schematic view of a TFT display panel according to still another embodiment, in which the data line detection configuration in the detection region is the same as that of the embodiment illustrated in FIG. 1A and is not described again here for simplicity. A gate detection line 212 is connected with all the gate lines 211 from the two display regions 10, and a gate detection pad 213 is provided at one end of the gate detection line 212. As a result, only a gate detection signal is applied to perform the detection of the circuits in the both display regions 10, which further simplifies mask process of the detection region and increases the detection efficiency. Furthermore, each display region corresponds to a group of an odd data detection line, an even data detection line, and a common electrode detection lines. Therefore, it is possible that, when the detection device applies detection signals at the gate detection pad or the odd and even data detection pads, if short of the gate lines or data lines occurs in the display region, the display region where the short occurs can be determined by the detection signal received through the odd and even data detection lines or the gate detection line, which further improves the detection efficiency.

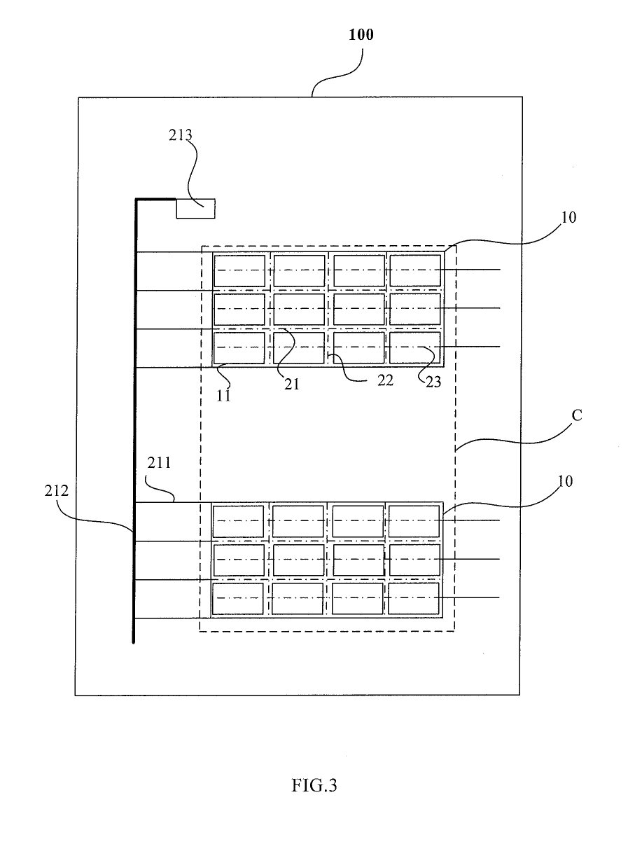

FIG. 4 is a structural schematic view of a TFT display panel according to yet another embodiment, in which the data line detection configuration in the detection region is the same as that of the embodiment illustrated in FIG. 1A and is not described again here for simplicity. A gate detection line 212 is connected with all the gate lines 211 from the two display regions 10, and gate detection pads 213 are provided at both ends of the gate detection line 212. As a result, in the case that the insulating substrate is in a relatively large area, a detection signal can be applied at both sides of the panel for detection, which further reduces the detection time, improves the production efficiency of the TFT display panel, and reduces the production cost. Furthermore, each display region corresponds to a group of an odd data detection line, an even data detection line, and a common electrode detection line. Therefore, it is possible that, when the detection device applies detection signals at the gate detection pads or the odd and even data detection pads, if short of the gate lines or data lines occurs in the display region, the display region where the short occurs can be determined by the detection signal received through the odd and even data detection lines, which further improves the detection efficiency.

In the above embodiments, two or more display regions can share an odd data detection line, an even data detection line, and a common electrode line, the explanation of which is not repeated here for simplicity.

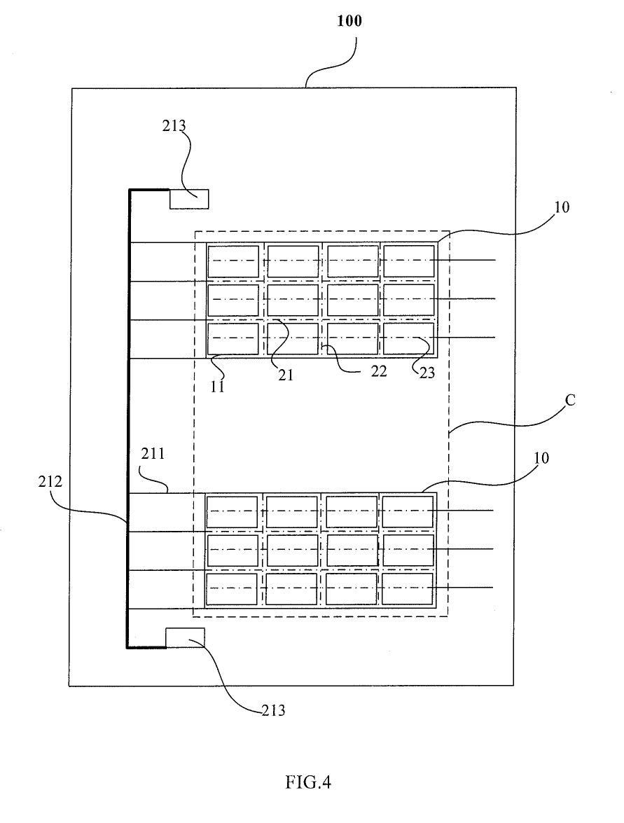

FIG. 5 is a flowchart illustrating a method for manufacturing a TFT display panel according to an embodiment of the present invention. In this embodiment, the method for manufacturing the TFT display panel, in which there is formed no intersection of gate detection lines in the detection region, may comprises the following steps.

Step 101. A substrate is provided, and on the substrate formed are gate lines and common electrode lines in the display region, and a gate detection line, odd and even data detection lines, a common electrode detection line, a gate detection pad, odd and even data detection pads, and a common electrode detection pad in the detection region, respectively.

Step 102. A gate insulating layer is deposited on the substrate.

Step 103. Data lines in the display region and via holes in the gate insulating layer, which connect data lines with the corresponding odd and even data detection lines are formed.

Step 104. A passivation layer is formed on the substrate, and via holes in the passivation layer, which expose the gate detection pads, the odd and even data detection pads, and the common electrode detection pads, respectively, for measurement are formed.

In the above embodiment of the method, the circuits including the gates of the TFTs, gate lines, a gate detection line, a gate detection pad, etc., are formed in the gate metal film, substantially simplifying the mask process of the TFT display panel and enabling the improved production efficiency of the TFT and the reduced production cost.

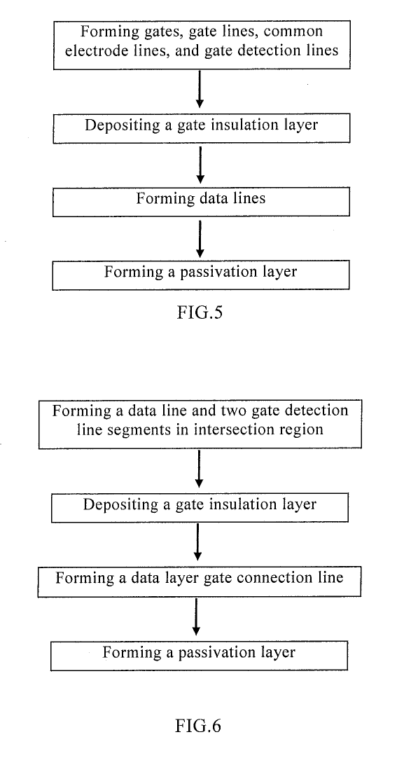

FIG. 6 is a flowchart illustrating another method for manufacturing a TFT display panel according to another embodiment of the present invention. In this embodiment, there is provided a method for manufacturing the TFT display panel, in which there is formed an intersection of gate detection lines in the detection region, and the method may comprise the following steps.

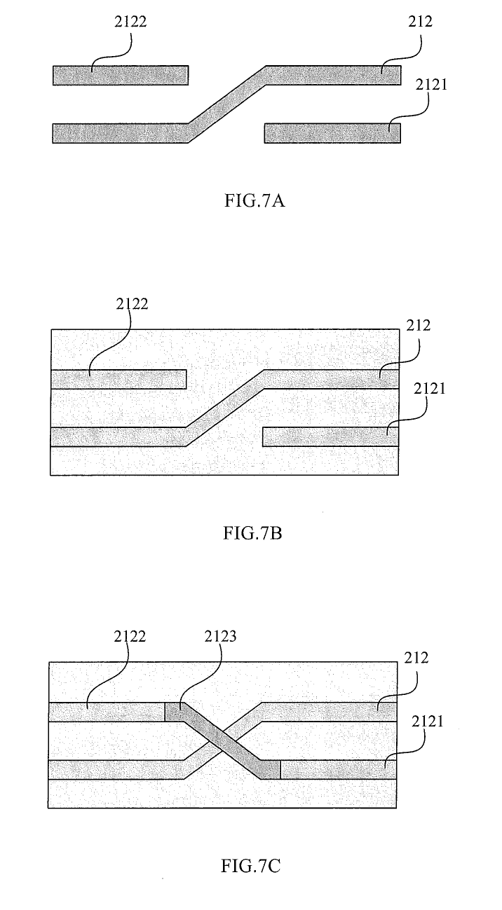

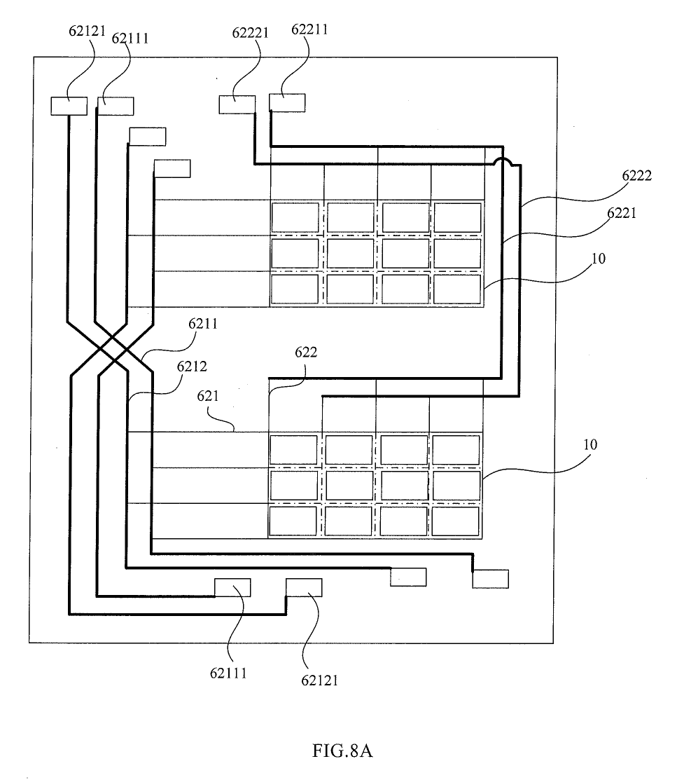

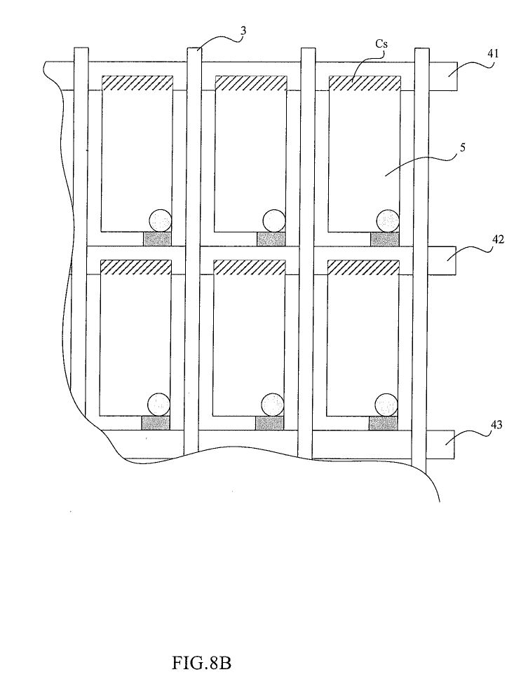

Step 201. A substrate is provided, and formed on the substrate are gate lines and common electrode lines in the display region, and gate detection lines, odd and even data detection lines, a common electrode detection line, gate detection pads, odd and even data detection pads, and a common electrode detection pad in the detection region. During the formation of the gate detection lines, only one complete gate detection line and two line segments of the other detection line, which is separated by the former complete one, are formed in the gate metal film. As shown in FIG. 7A, a gate detection line 212 separates the two line segments 2121, 2122 of the other gate detection line.

Step 202. A gate insulating layer is deposited on the substrate. The gate detection lines 212 and the gate detection line segments 2121, 2122 after deposition of the gate insulating layer are shown in FIG. 7B.

Step 203. Data lines as well as a data layer gate connection line in the intersection region of the gate detection lines for connecting the line segments of the other gate detection line are formed, so that the other gate detection line can be formed as a whole and as shown in FIG. 7C, the two ends of the data layer gate connection line 2123 overlap with the gate detection line segments 2121, 2122, respectively. Via holes are formed in the overlapping portions and are filled with conductive materials so as to electrically connect the gate detection line segment 2121 in the gate metal film and the gate connection lines 2123 in the date metal film as well as the gate detection line segment 2122 in the gate metal film and the gate connection lines 2123 in the date metal film, completing the other gate detection line 212. Via holes are formed in the gate insulating layer to connect data lines with the corresponding odd and even data detection lines.

Step 204. A passivation layer is formed on the substrate, and via holes in the passivation layer, which expose the gate detection pads, the odd and even data detection pads, and the common electrode detection pads, respectively, for measurement are formed.

In the embodiment of the present invention, only a small thin film region in the data metal film is used to realize the connection of the gate detection line, which substantially simplifies the mask process for the TFT display panel, increases the production efficiency of the TFT, and reduces the production cost.

In the above exemplary methods, for the purpose of forming via holes in the passivation layer, which expose the gate detection pads, the odd and even data detection pads, and the common electrode detection pads for measurement, it is necessary to perform a multilayer etching on the passivation layer and the underlying gate insulating layer deposited on the substrate to form the via holes. With respect to the process of multilayer etching for form the via holes, since the passivation layer and the gate insulating layer generally are generally the same in characteristics and are nonmetallic material, the etching methods that have a very high selectivity with respect to metal and nonmetallic material may be selected. That is, the etching on insulating layer may not substantially damage the metal layer, so that the etching directivity can be controlled during the multilayer etching to ensure the etching quality of via holes.

Although the present invention has been described in detail referring to the preferred embodiments, the above embodiments are used only for illustration and not for the purpose of limitation. Accordingly, it will be understood by those of ordinary skill in the art that it is possible to use other materials and equipments if necessary, and that various modifications or equivalent alterations may be made to the embodiments of the present invention without departing from the spirit and scope of the present invention as set forth in the following claims.

1. A thin film transistor (TFT) display panel, comprising:
at least two display regions, which are formed on an insulting substrate and each comprise gate lines, data lines, and common electrode lines arranged between the neighboring gate lines; and
an detection region, which is formed on the insulating substrate and in the periphery of the display regions and comprises gate lines led out of the display region, a gate detection line for detection which is connected with the gate lines, a gate detection pad connected with the gate detection line, data lines led out of the display region, odd and even data detection lines for detection which are connected with the data lines, odd and even data detection pads correspondingly connected with the odd and even data detection lines, common electrode lines led out of the display region, a common electrode detection line connected with the common electrode lines, and a common electrode detection pad connected with the common electrode detection lines,
wherein the gate detection line is correspondingly connected with all gate lines from at least one of the display regions.

2. The TFT display panel according to claim 1, wherein one gate detection line is correspondingly connected with all the gate lines from one of the display regions.

3. The TFT display panel according to claim 2, wherein the gate detection pad is provided at one end of the gate detection line.

4. The TFT display panel according to claim 2, wherein there are gate detection pads that are provided at both ends of the gate detection line.

5. The TFT display panel according to claim 1, wherein one gate detection line is correspondingly connected with all the gate lines from the least two display regions.

6. The TFT display panel according to claim 5, wherein the gate detection pad is provided at one end of the gate detection line.

7. The TFT display panel according to claim 5, wherein there are gate detection pads that are provided at both ends of the gate detection line.

8. The TFT display panel according to claim 1, wherein the odd and even data detection lines and the common electrode detection line each are correspondingly connected with the odd and even data lines and the common electrode lines led out of one of the display regions, and the odd and even data detection pads and the common electrode detection pad are correspondingly arranged at an end of the odd and even data detection lines and the common electrode detection line, respectively.

9. A method for manufacturing a thin film transistor (TFT) display panel, comprising:
forming on a substrate gate lines and common electrode lines of at least two display regions, and a gate detection line, odd and even data detection lines, a common electrode detection line, a gate detection pad, odd and even data detection pads, and a common electrode detection pad in a detection region in the periphery of the display regions, wherein the gate detection line is correspondingly connected with all gate lines from at least one of the display regions, and the common electrode detection line is connected with the common electrode lines, and the gate detection pad, odd and even data detection pads, and the common electrode detection pad are formed at an end of the gate detection line, odd and even data detection lines, the common electrode detection line, respectively;
forming a gate insulating layer on the substrate and forming first via holes in the gate insulating layer which lead to the odd and even data detection lines, respectively;
forming data lines and connecting the odd and even data lines with corresponding odd and even data detection lines respectively through the first via holes; and
forming a passivation layer and second via holes in the passivation which expose the gate detection pads, the odd and even data detection pads, and the common electrode detection pads, respectively.

10. The method according to claim 9, wherein forming two gate detection lines on the substrate which intersect with each other, and forming in an intersection region two gate detection line segments for one gate detection line that are separated by the other gate detection line;
forming third via holes in the gate insulating layer which lead to the two gate detection line segments, respectively; and
forming a data layer gate connection line which connects the two gate detection line segments through the third via holes at the time forming the data lines.

11. The method according to claim 9, wherein one gate detection line is correspondingly connected with all the gate lines from the least two display regions.

12. A method for detecting the thin film transistor (TFT) including:
at least two display regions, which are formed on an insulting substrate and each comprise gate lines, data lines, and common electrode lines arranged between the neighboring gate lines, and
an detection region, which is formed on the insulating substrate and in the periphery of the display regions and comprises gate lines led out of the display region, a gate detection line for detection which is connected with the gate lines, a gate detection pad connected with the gate detection line, data lines led out of the display region, odd and even data detection lines for detection which are connected with the data lines, odd and even data detection pads correspondingly connected with the odd and even data detection lines, common electrode lines led out of the display region, a common electrode detection line connected with the common electrode lines, and a common electrode detection pad connected with the common electrode detection lines,
wherein the gate detection line is correspondingly connected with all gate lines from at least one of the display regions, the method comprising:
applying a gate detection signal to the gate lines through the gate detection pad;
applying data detection signals to the odd and even data lines through the odd and even data detection pads, respectively; and
applying a voltage signal opposite to the data detection signals applied to the odd and even data lines to the common electrode line through the common electrode detection pad, thereby performing detection on the display regions.
